(19) United States
(12) Patent Application Publication
(10) Pub. No.: US 2024/0404980 A1
(43) Pub. Date: Dec. 5, 2024

(54) BOND WIRE HAVING A RECYCLED THERMOPLASTIC CORE WITH CONDUCTIVE FILLERS

(71) Applicant: Western Digital Technologies, Inc., San Jose, CA (US)

(72) Inventors: MUHAMAD RIDHWAN HAFIZ BIN ROSDI, PULAU PINANG (MY); CINDIRELLA QUINIT NOROMOR, PULAU PINANG (MY); DUNSOON TESICO, PENANG (MY); MUHAMMAD FAIZUL MOHD YUNUS, PENANG (MY)

(21) Appl. No.: 18/360,361

(22) Filed: Jul. 27, 2023

Related U.S. Application Data
(60) Provisional application No. 63/505,617, filed on Jun. 1, 2023.

(51) Int. Cl. H01L 23/00

(52) U.S. Cl. CPC H01L 24/43; H01L 24/45; H01L 2224/432; H01L 2224/4519; H01L 2224/45393; H01L 2224/45565; H01L 2224/45644; H01L 2924/01079; H01L 2924/37001

(57) ABSTRACT

A bond wire has an outer layer formed of a conductive material and a core formed of a non-conductive material. The non-conductive material is blended with conductive fillers to enhance electrical and/or thermal conductivity characteristics of the bond wire.

### CROSS-REFERENCE TO RELATED APPLICATIONS

The present application claims priority to U.S. Provisional Application 63/505,617 entitled “BOND WIRE HAVING A RECYCLED THERMOPLASTIC CORE WITH CONDUCTIVE FILLERS”, filed Jun. 1, 2023, the entire disclosure of which is hereby incorporated by reference in its entirety.

### BACKGROUND

Technological advancements and rapid growth of miniaturized circuits, including system-on-chip devices, memory devices, and so on, have caused bond wires to become an essential element of electronic assemblies. Typically, bond wires are used for making interconnections between integrated circuits (ICs) and other electronic components.

Generally, bond wires are made of materials that have a low resistance and good electrical and thermal conductivity. Gold is widely for bond wires and is generally preferred over other materials such as copper, aluminum, and/or silver because gold is more easily processed when compared with these other materials. However, gold is expensive. As a result, the cost of making electronic devices with gold bond wires increases the cost of the devices.

Accordingly, it would be beneficial to make bond wires less expensive by using other types of materials without significantly affecting the electrical and thermal conductivity characteristics of the bond wires.

### SUMMARY

The present application describes a bond wire having a thermoplastic core. For example, the bond wire has an outer layer that is formed of gold, or another conductive material, while the core of the bond wire is formed of a non-conductive, thermoplastic material. In an example, the thermoplastic material may be formed of recycled polymers or other recycled materials.

In order to increase the overall electrical and/or thermal conductivity characteristics of the bond wire, conductive fillers are blended with the thermoplastic material that comprises the core. As such, the thermoplastic core may significantly reduce the cost of the bond wire without significantly affecting the quality of the bond wire.

Accordingly, the present application describes a method for manufacturing a bond wire. The method includes providing a core material to a co-extrusion die of an extruder. In an example, the core material comprises a conductive filler material blended with a non-conductive material. The method also includes providing a conductive material to the co-extrusion die of the extruder. When the core material and the non-conductive material have been provided to the co-extrusion die of the extruder, the core material forms a core as the core material passes through the co-extrusion die during a co-extrusion process. Additionally, the conductive material forms an outer layer on the core during the co-extrusion process to create the bond wire.

In another example, a bond wire is described. In an example, the bond wire includes a core. The core is formed of a non-conductive material and a conductive filler blended with the non-conductive material. The bond wire also includes an outer layer that surrounds the core. In an example, the outer layer is formed of a conductive material.

The present application also describes a bond wire for a semiconductor device. In an example, the bond wire includes a core means. The core means is formed of a non-conductive recycled material and a conductive filler that is blended with the non-conductive recycled material. In an example, the core means comprises between approximately ten percent to approximately forty percent of the bond wire. The bond wire also includes a coating means surrounding the core means. In an example, the coating means is a conductive material.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a cross-section view of a bond wire according to an example.

FIG. 2 illustrates a co-extrusion process that is used to make a bond wire having a non-conductive core according to an example.

FIG. 3 illustrates a method for making a material that is used to form a core of a bond wire according to an example.

FIG. 4 illustrates a method for manufacturing a bond wire having a non-conductive core according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems, or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

The present application describes a wire that may be used in various semiconductor devices. In an example, the wire is a bond wire. For example, the bond wire may be used to connect one component of the semiconductor device to another component of the semiconductor device.

However, unlike typical bond wires that are formed form a single material such as gold, copper, or aluminum, the bond wire described herein includes a core (or a core layer) and an outer layer. In an example, the core is formed of a thermoplastic material, or a non-conductive material, while the outer layer is formed of a conductive material (e.g., gold). In an example, the thermoplastic material may be formed of recycled materials such as paper, metal, glass, rubber, porcelain, ceramic, plastic, and/or any other type of recyclable materials.

In order to increase the electrical and/or thermal conductivity characteristics of the bond wire, the thermoplastic core is blended with a conductive filler or pieces of a conductive material. In an example, the conductive filler is graphene, a metallic powder, metallic shavings, metallic pieces, or other conductive materials.

Depending on an application for the bond wire, the thermoplastic core may have different dimensions and/or different concentrations of the conductive material/filler. Likewise, the outer surface or the outer layer of the bond wire may have different dimensions and/or gold composition.

For example, in one application, approximately ten percent of the bond wire may be formed of the thermoplastic core while the remaining ninety percent of the bond wire is formed of gold. Additionally, the thermoplastic core may be blended with a particular amount of conductive filler in order to achieve desired electrical and/or thermal conductivity characteristics for the bond wire.

In another example, approximately forty percent of the bond wire may be formed of the thermoplastic core while the remaining sixty percent of the bond wire is formed of gold. The thermoplastic core may be blended with a particular amount of conductive filler in order to achieve desired electrical and/or thermal conductivity characteristics for this particular application.

Using different proportions and/or types of non-conductive materials, and blending the non-conductive materials with a variety of different conductive materials, enables the production of bond wires having different thermal, electrical and/or mechanical properties. The thermal, electrical and/or mechanical properties may include, but are not limited to, electrical conductivity, electrical resistivity, strength, sturdiness, elasticity, density, and/or flexibility. Although bond wires are specifically mentioned, any number of electrical wires may be manufactured using the various processes described herein.

Accordingly, many technical benefits may be realized including, but not limited to, reducing the cost of bond wires without unduly sacrificing electrical and/or thermal conductivity characteristics of the bond wires, increasing a mechanical strength or sturdiness of the bond wires and enabling bond wires to be manufactured with specific compositions based on an intended use of the bond wires.

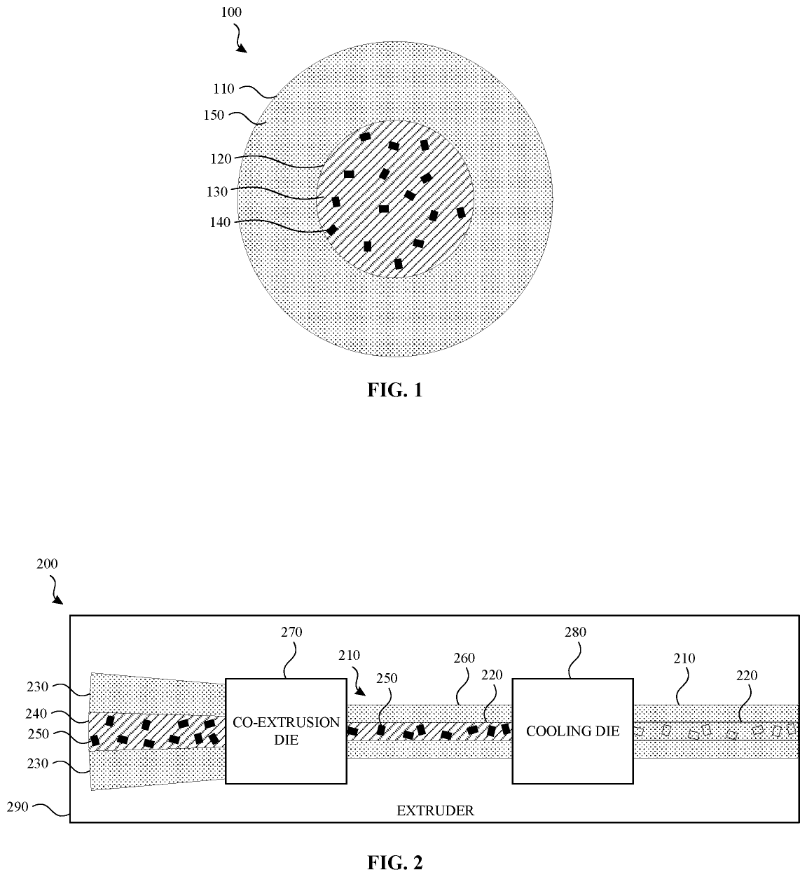

These and other examples are described in more detail with respect to FIG. 1-FIG. 4.

FIG. 1 is a cross-section view of a bond wire 100 according to an example. The bond wire 100 may be used in a semiconductor device. For example, the bond wire 100 may be used to connect various components of a semiconductor device to other components of the semiconductor device.

In an example, the bond wire 100 includes multiple layers. For example, the bond wire 100 may include an outer layer 110 (or a coating layer) and an inner layer or a core 120. Although a single outer layer 110 is shown surrounding the core 120, the bond wire 100 may have multiple different layers surrounding the core 120. In such an example, each layer may be formed of the same material or a different material.

The core 120 of the bond wire 100 may be formed of different materials. For example, the core 120 may be at least partially formed of a non-conductive material 130. The non-conductive material 130 may be a thermoplastic material. In another example, the non-conductive material 130 includes recycled materials. The recycled materials may include, but are not limited to, aluminum, metal, paper, glass, rubber, plastic, porcelain, ceramic and/or other recyclable materials.

The core 120 may also include a conductive material or a conductive filler 140. In an example, the conductive filler 140 is blended with the non-conductive material 130. Blending the conductive filler 140 with the non-conductive material 130 enhances the electrical and/or thermal conductivity characteristics or properties of the bond wire 100.

In an example, an amount of the conductive filler 140 that is blended with the non-conductive material 130 may be based, at least in part, on a desired or determined use of the bond wire 100. For example, a ratio of the non-conductive material 130 to the conductive filler 140 in the core 120 may be based on a particular application of the bond wire 100. Likewise, a ratio of the non-conductive material 130 to the conductive filler 140 in the core 120 may be based on another particular application of the bond wire 100.

In another example, the conductive filler 140 may have various sizes or dimensions. As such, the size and/or the dimensions of the various pieces of the conductive filler 140 may also vary based on a desired or determined use of the bond wire 100. In yet another example, the ratio of the non-conductive material 130 to the conductive filler 140 may be determined based, at least in part, on a desired set of electrical properties of the bond wire 100 and/or a desired set of mechanical properties of the bond wire 100. In yet another example, a type of the conductive filler 140 and/or a type of the non-conductive material 130 may change or otherwise be selected based, at least in part, on desired electrical and/or mechanical properties of the bond wire 100.

In an example, the conductive filler 140 is graphene. In another example, the conductive filler 140 is a metallic powder, metallic pieces, metallic shavings or the like. Although specific conductive materials are mentioned, other conductive materials, in various combinations, may be used. Further, and as previously discussed, an amount, size and/or type of the conductive filler 140 may vary.

In an example, the core 120 may make up a particular percentage of the overall composition of the bond wire 100. For example, the core 120 may comprise between approximately ten percent to approximately forty percent of the of the bond wire 100. Although specific ranges have been given, the core 120 may comprise less than ten percent or more than forty percent of the total composition of the bond wire 100.

The outer layer 110 of the bond wire 100 may be made from a second type of material. In an example, the outer layer 110 is formed of a conductive material 150 such as, for example, at least one type of metal. The at least one type of metal may include, but is not limited to, gold, silver, copper, aluminum or some other metal with conductive properties. In an example, the conductive material 150 may include one or more metals that are blended together such as, for example, gold blended with copper.

The outer layer 110 may make up a particular percentage of the overall composition of the bond wire 100. In an example, the percentage may be based, at least in part, on an intended use and/or on desired electrical and/or mechanical properties of the bond wire 100. For example, the outer layer 110 may have a first thickness or diameter based on a first desired/intended use and may have a second thickness or diameter based on a second desired/intended use. Likewise, the outer layer 110 may be formed of different conductive materials 150 based on a particular desired/intended use.

FIG. 2 illustrates a co-extrusion process 200 that is used to make a bond wire 210 having a non-conductive core 220 according to an example. In an example, an extruder 290 may execute the co-extrusion process 200 to make the bond wire 210. The bond wire 210 that is made using the co-extrusion process 200 may be similar to the bond wire 100 shown and described with respect to FIG. 1.

In an example, a single extruder 290 may execute the co-extrusion process 200 to make the bond wire 210. In another example, multiple extruders may execute one or more steps of the co-extrusion process 200 to make the bond wire 210. However, in the examples that follow, reference is made to a single extruder 290.

In an example, a first material 230 is provided to the extruder 290. The first material 230 may be a conductive material that will form an outer layer 260 of the bond wire 210. In an example, the first material 230 is gold. Although gold is specifically mentioned, the first material 230 may be any conductive material such as, but not limited to silver, copper, aluminum, or other conductive metals.

As part of, or prior to, the co-extrusion process 200, the first material 230 may undergo various processes so that it may be used to form the outer layer 260 of the bond wire 210. For example, the first material 230 may undergo a doping process. In another example, a melting process may be used to ensure the first material 230 is in a molten state or a softened state. In an example, the first material 230 may be provided to the extruder 290 in the molten state. In another example, the extruder 290 may melt the first material 230 so the first material 230 is in the molten state.

The extruder 290 may receive a second material 240. In an example, the second material 240 is a non-conductive material that forms a core 220 of the bond wire 210. In an example, the non-conductive material is a polymer or a thermoplastic material. As previously indicated, the non-conductive material may be formed of recycled materials.

The second material 240 may also include conductive fillers 250 or conductive filler materials. The amount of conductive fillers 250 provided in the second material 240 may vary based on various factors such as previously described.

In an example, the second material 240 may be provided to the extruder 290 in a pelletized form. Once received, the extruder 290 may melt the second material 240 such that the second material 240 is in a molten state or a softened state. In another example, the second material 240 may be provided to the extruder 290 in the molten/softened state. In an example, conductive fillers 250 may be added to the second material 240 when the second material 240 is in the molten state and/or when the second material 240 is provided to the extruder 290.

When the first material 230 and the second material 240 are in the molten state, the extruder 290 causes the first material 230 and the second material 240 to pass through a co-extrusion die 270. In an example, the co-extrusion die 270 may include multiple channels or apertures that enables or allows the first material 230 to flow separately from the second material 240.

The multiple channels may merge within the co-extrusion die 270 in such a way as to enable the second material 240 to form the core 220 while the first material 230 flows around the core 220 to form the outer layer 260 of the bond wire 210. Additionally, the co-extrusion die 270 and/or the extruder 290 may control a flow rate of the first material 230, a flow rate of the second material 240, a temperature of the first material 230, a temperature of the second material 240, and/or a thickness/diameter of the core 220 and/or of the outer layer 260.

In an example, once the bond wire 210 has been extruded/formed by the co-extrusion die 270, the bond wire 210 may pass through a cooling chamber or a cooling die 280. The cooling die 280 cools the extruded bond wire 210. Additionally, the cooling die 280 may be designed or otherwise configured to match a shape and/or a diameter of the bond wire 210 which may help ensure that the bond wire 210 is uniformly cooled along its length.

In an example, the bond wire 210 may also undergo an annealing process. In an example, any known annealing process may be used. In addition to the annealing process, the bond wire 210 may undergo various other processes (e.g., winding, property checks, visual inspection) to ensure the bond wire 210 is ready for use in various semiconductor devices.

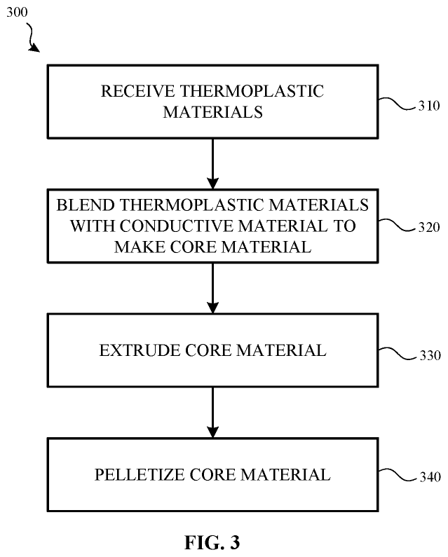

FIG. 3 illustrates a method 300 for creating a material that is used to make a core of a bond wire according to an example. In an example, the method 300 may be used to make the second material 240 that is used to form the non-conductive core 220 of the bond wire 210 shown and described with respect to FIG. 2.

Method 300 begins when thermoplastic materials are received (310). In an example, the thermoplastic materials are recycled materials that have undergone a recycling process. For example, the thermoplastic materials may have been shredded, washed, melted, extruded and/or pulverized, or otherwise prepared for subsequent use. Whether recycled or not, the thermoplastic materials may be provided/received in a pelletized or granular form for subsequent processing.

The thermoplastic materials are then blended (320) with conductive filler materials to make a core material. In an example, the term “core material” refers to the material that will be used to make the non-conductive core of the bond wire. In an example, the type(s) and/or the amount(s) of conductive filler material that is blended with the thermoplastic material may be based, at least in part, on desired electrical and/or thermal conductivity characteristics of the bond wire.

As part of, or in addition to, the blending process, the core material may also be extruded (330). In an example, any known extrusion process may be used. Once extruded, the core material may be pelletized (340) or otherwise prepared for subsequent use. For example, the pelletized core material may be used as the second material 240 in the extrusion process 200 shown and described with respect to FIG. 2.

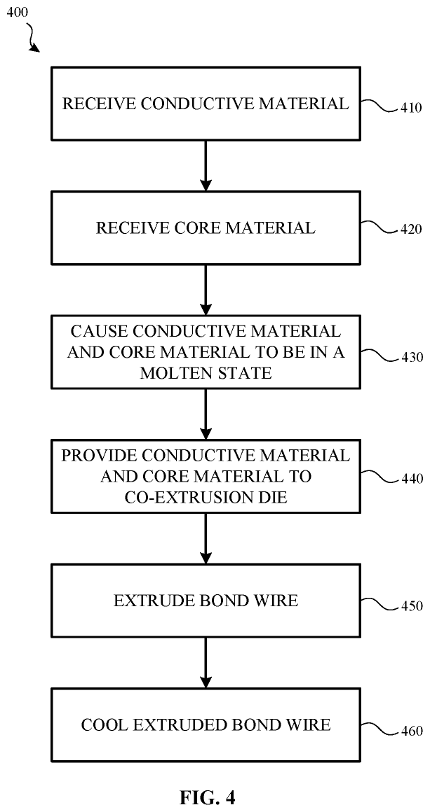

FIG. 4 illustrates a method 400 for manufacturing a bond wire having a non-conductive core according to an example. In an example, the bond wire that is made using the method 400 may be the bond wire 100 shown and described with respect to FIG. 1 and/or the bond wire 210 shown and described with respect to FIG. 2.

In an example, the method 400 begins when conductive material is received (410) by an extruder. The extruder may be the extruder 290 that performs the co-extrusion process 200 shown and described with respect to FIG. 2. The conductive material may be used to form an outer layer of the bond wire. In an example, the conductive material is gold, although other conductive materials may be used.

In addition to receiving conductive materials, the extruder may also receive (420) core material. In an example, the core material is a non-conductive material that will be used to form a core of the bond wire. The non-conductive material may be a polymer or a thermoplastic material. In an example, the non-conductive material may be formed of recycled materials. The core material may also include a conductive filler or conductive filler materials. For example, the core material that is provided to the extruder may be the core material that is generated by the method 300 shown and described with respect to FIG. 3.

When the conductive material and the core material has been received by, or otherwise provided to, the extruder, the extruder causes (430) the conductive material and the core material to be in a molten state. The conductive material and the core material is then provided (440) to a co-extrusion die.

In an example, the co-extrusion die includes multiple channels or apertures that allows the conductive material to initially flow separately from the core material. However, the multiple channels may merge within the co-extrusion die during an extrusion (450) process in such a way that the core material forms a core of the bond wire while the conductive material flows around the core to form the outer layer of the bond wire.

When the bond wire has been extruded/formed by the co-extrusion die, the extruded bond wire is cooled (460). In an example, the extruded bond wire is cooled by causing the bond wire to pass through a cooling chamber or a cooling die. Additional processes (e.g., annealing, winding), such as those previously described with respect to FIG. 2, may additionally be performed.

Based on the above, examples of the present disclosure describe a method for manufacturing a bond wire, comprising: providing a core material to a co-extrusion die of an extruder, the core material comprising a conductive filler material blended with a non-conductive material; providing a conductive material to the co-extrusion die of the extruder; causing the core material to form a core as the core material passes through the co-extrusion die during a co-extrusion process, the core having the conductive filler material; and causing the conductive material to form an outer layer on the core during the co-extrusion process to create the bond wire. In an example, the method also includes providing the bond wire to a cooling die to cool the bond wire. In an example, a ratio of the conductive filler material to the non-conductive material is based, at least in part, on expected thermal conductivity characteristics of the bond wire. In an example, the method also includes determining a diameter of the core; and causing the co-extrusion die to form the core having the determined diameter. In an example, the diameter of the core is based, at least in part, on expected thermal conductivity characteristics of the bond wire. In an example, the conductive material is gold. In an example, the conductive filler material is one or more of graphene and metallic powder. In an example, the non-conductive material is comprised of recycled materials. In an example, the core comprises between approximately ten percent to approximately forty percent of the bond wire.

Additional examples describe a bond wire, comprising: a core comprising: a non-conductive material; and a conductive filler blended with the non-conductive material; and an outer layer surrounding the core, the outer layer comprising a conductive material. In an example, a ratio of the conductive filler to the non-conductive material is based, at least in part, on expected thermal conductivity characteristics of the bond wire. In an example, a diameter of the core is based, at least in part, on expected thermal conductivity characteristics of the bond wire. In an example, the outer layer is comprised of gold. In an example, the conductive filler is one or more of graphene and metallic powder. In an example, the non-conductive material is comprised of recycled materials. In an example, the core comprises between approximately ten percent to approximately forty percent of the bond wire.

In yet another example, a bond wire for a semiconductor device is described. The bond wire includes a core means, comprising: a non-conductive recycled material; and a conductive filler blended with the non-conductive recycled material, the core means comprising between approximately ten percent to approximately forty percent of the bond wire; and a coating means surrounding the core means, the coating means comprising a conductive material. In an example, the conductive filler is one or more of graphene and metallic powder. In an example, a ratio of the conductive filler to the non-conductive recycled material is based, at least in part, on expected thermal conductivity characteristics of the bond wire. In an example, the conductive material is selected from a group comprising gold, silver, aluminum and copper.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure. For example, while the wire described herein may be used as a bond wire in an electronic device, larger diameter wires may be formed using the described method and having the described structure, and such larger diameter wires may have uses outside of electronic device assembly.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to flowchart diagrams and/or block diagrams of methods and apparatuses according to embodiments of the disclosure. It will be understood that each block of the flowchart diagrams and/or block diagrams, and combinations of blocks in the flowchart diagrams and/or block diagrams, can be implemented by computer program instructions. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method for manufacturing a bond wire, comprising:
providing a core material to a co-extrusion die of an extruder, the core material comprising a conductive filler material blended with a non-conductive material;
providing a conductive material to the co-extrusion die of the extruder;
causing the core material to form a core as the core material passes through the co-extrusion die during a co-extrusion process, the core having the conductive filler material; and
causing the conductive material to form an outer layer on the core during the co-extrusion process to create the bond wire.

2. The method of claim 1, further comprising providing the bond wire to a cooling die to cool the bond wire.

3. The method of claim 1, wherein a ratio of the conductive filler material to the non-conductive material is based, at least in part, on expected thermal conductivity characteristics of the bond wire.

4. The method of claim 1, further comprising:
determining a diameter of the core; and
causing the co-extrusion die to form the core having the determined diameter.

5. The method of claim 4, wherein the diameter of the core is based, at least in part, on expected thermal conductivity characteristics of the bond wire.

6. The method of claim 1, wherein the conductive material is gold.

7. The method of claim 1, wherein the conductive filler material is one or more of graphene and metallic powder.

8. The method of claim 1, wherein the non-conductive material is comprised of recycled materials.

9. The method of claim 1, wherein the core comprises between approximately ten percent to approximately forty percent of the bond wire.

10. A bond wire, comprising:
a core comprising:
a non-conductive material; and
a conductive filler blended with the non-conductive material; and
an outer layer surrounding the core, the outer layer comprising a conductive material.

11. The bond wire of claim 10, wherein a ratio of the conductive filler to the non-conductive material is based, at least in part, on expected thermal conductivity characteristics of the bond wire.

12. The bond wire of claim 10, wherein a diameter of the core is based, at least in part, on expected thermal conductivity characteristics of the bond wire.

13. The bond wire of claim 10, wherein the outer layer is comprised of gold.

14. The bond wire of claim 10, wherein the conductive filler is one or more of graphene and metallic powder.

15. The bond wire of claim 10, wherein the non-conductive material is comprised of recycled materials.

16. The bond wire of claim 10, wherein the core comprises between approximately ten percent to approximately forty percent of the bond wire.

17. A bond wire for a semiconductor device, comprising:
a core means, comprising:
a non-conductive recycled material; and
a conductive filler blended with the non-conductive recycled material, the core means comprising between approximately ten percent to approximately forty percent of the bond wire; and
a coating means surrounding the core means, the coating means comprising a conductive material.

18. The bond wire of claim 17, wherein the conductive filler is one or more of graphene and metallic powder.

19. The bond wire of claim 17, wherein a ratio of the conductive filler to the non-conductive recycled material is based, at least in part, on expected thermal conductivity characteristics of the bond wire.

20. The bond wire of claim 17, wherein the conductive material is selected from a group comprising gold, silver, aluminum and copper.
